(19) United States
(12) Patent Application Publication
(10) Pub. No.: US 2022/0084814 A1
(43) Pub. Date: Mar. 17, 2022

(54) APPARATUS FOR PROCESSING SUBSTRATE

(71) Applicant: SEMES CO., LTD., Cheonan-si (KR)

(72) Inventors: SANGMIN LEE, Seoul (KR); JOO JIB PARK, Asan-si (KR); BOONG KIM, Cheonan-si (KR); JONG DOO LEE, Gyeongju-si (KR)

(21) Appl. No.: 17/531,741

(22) Filed: Nov. 20, 2021

Related U.S. Application Data
(63) Continuation of application No. 16/396,906, filed on Apr. 29, 2019.

(30) Foreign Application Priority Data
Apr. 30, 2018 (KR) 10-2018-0049778

(51) Int. Cl. H01L 21/02; H01L 21/687; H01L 21/67; B08B 5/02

(52) U.S. Cl. CPC H01L 21/02101; B08B 5/02; H01L 21/67051; H01L 21/68764

(57) ABSTRACT

The apparatus includes a chamber having a first body and a second body that are combined with each other to form a processing space inside, an actuator that moves a relative position between the first body and the second body to enable a position change between a closed position in which the processing space is sealed from the outside and an open position in which the processing space is open to the outside, the actuator to sequentially perform a high-speed closing step of moving the first body or the second body at a first speed and a low-speed closing step of moving the first body or the second body at a second speed lower than the first speed, at the time of the position change from the open position to the closed position.

### CROSS-REFERENCE TO RELATED APPLICATIONS

This application is a continuation of U.S. patent application Ser. No. 16/396,906 filed Apr. 29, 2019, which is titled “APPARATUS AND METHOD FOR PROCESSING SUBSTRATE,” which claims the benefit of Korean Patent Application No. 10-2018-0049778 filed on Apr. 30, 2018. The entire content of the above identified application is incorporated herein by reference.

### BACKGROUND

Embodiments of the inventive concept described herein relate to an apparatus and method for processing a substrate, and more particularly, relate to an apparatus and method for processing a substrate in a high-pressure atmosphere.

In order to manufacture semiconductor devices, desired patterns are formed on a substrate through various processes such as photolithography, etching, ashing, ion implantation, thin film deposition, and the like. Various processing liquids are used in the processes, and contaminants and particles are generated during the processes. A cleaning process for removing the contaminants and the particles from the substrate is necessarily performed before and after each process.

In the cleaning process, the substrate is generally processed with a chemical and a rinsing solution and then dried. The drying process is a process for drying the rinsing solution remaining on the substrate. In the drying process, the rinsing solution on the substrate is replaced by an organic solvent such as isopropyl alcohol (IPA), the surface tension of which is lower than that of the rinsing solution, and thereafter the organic solvent is removed. However, due to the scaling-down of the critical dimension (CD) between the patterns formed on the substrate, it is not easy to remove the organic solvent remaining in the spaces between the patterns.

Recently, a process of removing an organic solvent remaining on a substrate by using a supercritical fluid has been used. The supercritical process is performed in a high-pressure space sealed from the outside, in order to satisfy a specific condition of the supercritical fluid.

FIG. 1 is a sectional view illustrating a general supercritical processing apparatus. Referring to FIG. 1, a process chamber for performing supercritical processing has a first body 2 and a second body 4. The first body 2 and the second body 4 are combined together to form a processing space inside. The first body 2 and the second body 4 move relative to each other to open or close the processing space. The first body 2 and the second body 4 are moved toward or away from each other to close or open the processing space. The first and second bodies 2 and 4 are moved at constant speed.

In order to seal the processing space under a high-pressure condition, cylinders have to apply a strong force to move the first body 2 and the second body 4 toward each other. Furthermore, time taken to open or close the processing space has to be reduced to increase substrate throughput. Therefore, the first and second bodies 2 and 4 are moved at high speed in the process of opening or closing the processing space.

However, while the processing space is being closed, the first body 2 and the second body 4 collide with each other with great force. Hence, the first body 2 and the second body 4 are damaged, and the air-tightness of the processing space is degraded.

Furthermore, at the beginning of the processing-space opening operation, the processing space expands so that the pressure inside the processing space temporarily becomes lower than the pressure outside the processing space, and thus particles are introduced into the processing space from the outside.

### SUMMARY

Embodiments of the inventive concept provide an apparatus and method for preventing damage to bodies in a process of opening or closing a processing space formed by the bodies.

Embodiments of the inventive concept provide an apparatus and method for preventing introduction of particles into a processing space from the outside in a process of opening the processing space.

According to an exemplary embodiment, an apparatus for processing a substrate in a high-pressure atmosphere includes a chamber having a first body and a second body that are combined with each other to form a processing space inside, an actuator that moves a relative position between the first body and the second body to enable a position change between a closed position in which the processing space is sealed from the outside and an open position in which the processing space is open to the outside, a substrate support unit that supports the substrate in the processing space, a gas supply unit that supplies a gas into the processing space to process the substrate, and a controller that controls the actuator. The controller controls the actuator to sequentially perform a high-speed closing step of moving the first body or the second body at a first speed and a low-speed closing step of moving the first body or the second body at a second speed lower than the first speed, at the time of the position change from the open position to the closed position.

The controller may control the actuator to sequentially perform a low-speed opening step of moving the first body or the second body at a third speed and a high-speed opening step of moving the first body or the second body at a fourth speed higher than the third speed, at the time of the position change from the closed position to the open position.

The apparatus may further include a clamping member that clamps the chamber in the closed position and a movable member that moves the clamping member to a clamping position in which the clamping member clamps the first body and the second body or an unclamping position in which the clamping member is separated from the first body and the second body. The controller may control the gas supply unit and the movable member to perform a clamping step of moving the clamping member to the clamping position, a processing step of processing the substrate by supplying the gas into the processing space, with the chamber in the closed position, and an unclamping step of moving the clamping member to the unclamping position, between the low-speed closing step and the low-speed opening step.

In the processing step, the controller may control the actuator to apply a first pressure to move the first body and the second body toward each other and may control the gas supply unit to apply a second pressure by the gas supplied into the processing space. The second pressure may be higher than the first pressure.

The apparatus may further include an exhaust unit that releases an atmosphere in the processing space, and the controller may control the exhaust unit to make pressure in the processing space lower than the first pressure after the processing space is pressurized to the second pressure in the processing step.

The second pressure may be higher than a critical pressure of the gas.

According to an exemplary embodiment, a method for processing a substrate includes a high-speed closing step of moving a first body and a second body toward each other at a first speed, a low-speed closing step of moving the first body and the second body at a second speed lower than the first speed to bring the first body and second body into close contact with each other, and a processing step of processing the substrate with a gas in a processing space that the first body and the second body are combined together to form inside.

The method may further include a low-speed opening step of moving the first body and the second body away from each other at a third speed after the processing step and a high-speed opening step of moving the first body and the second body away from each other at a fourth speed higher than the third speed.

The method may further include a clamping step of clamping the first body and the second body brought into close contact with each other by a clamping member, between the low-speed closing step and the processing step and an unclamping step of releasing the clamping, between the processing step and the low-speed opening step.

In the processing step, a first pressure may be applied to move the first body and the second body toward each other and a second pressure may be applied to the processing space by the gas supplied into the processing space. The second pressure may be higher than the first pressure.

In the processing step, the first body and the second body may be moved away from each other and brought into close contact with the clamping member when pressure in the processing space is higher than the first pressure. The pressure in the processing space may be reduced to a pressure lower than the first pressure when the substrate is completely processed with the gas at the second pressure in the processing step, and the first body and the second body may be moved toward each other and spaced apart from the clamping member when the pressure in the processing space is lower than the first pressure.

In the processing step, the gas may be supplied in a supercritical state.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a sectional view illustrating a supercritical processing apparatus according to the related art;

FIG. 2 is a plan view illustrating substrate processing equipment according to an embodiment of the inventive concept;

FIG. 3 is a sectional view illustrating an apparatus for cleaning a substrate in a first process unit of FIG. 2;

FIG. 4 is a sectional view illustrating an apparatus for drying the substrate in a second process unit of FIG. 2;

FIG. 5 is a perspective view illustrating a housing of FIG. 4;

FIG. 6 is a perspective view illustrating a substrate support unit of FIG. 4;

FIG. 7 is a perspective view illustrating a clamping member of FIG. 4;

FIG. 8 is a flowchart illustrating a process of processing a substrate using the apparatus of FIG. 4;

FIG. 9 is a graph depicting the position of a second body in each step of the flowchart illustrated in FIG. 8; and

FIGS. 10 to 17 are views illustrating the process of processing the substrate using the apparatus of FIG. 4.

### DETAILED DESCRIPTION

The inventive concept may, however, be embodied in different forms and should not be constructed as limited to the embodiments set forth herein. Rather, these embodiments are provided so that the inventive concept will be thorough and complete, and will fully convey the scope of the inventive concept to those skilled in the art. Accordingly, in the drawings, the dimensions of components are exaggerated for clarity of illustration.

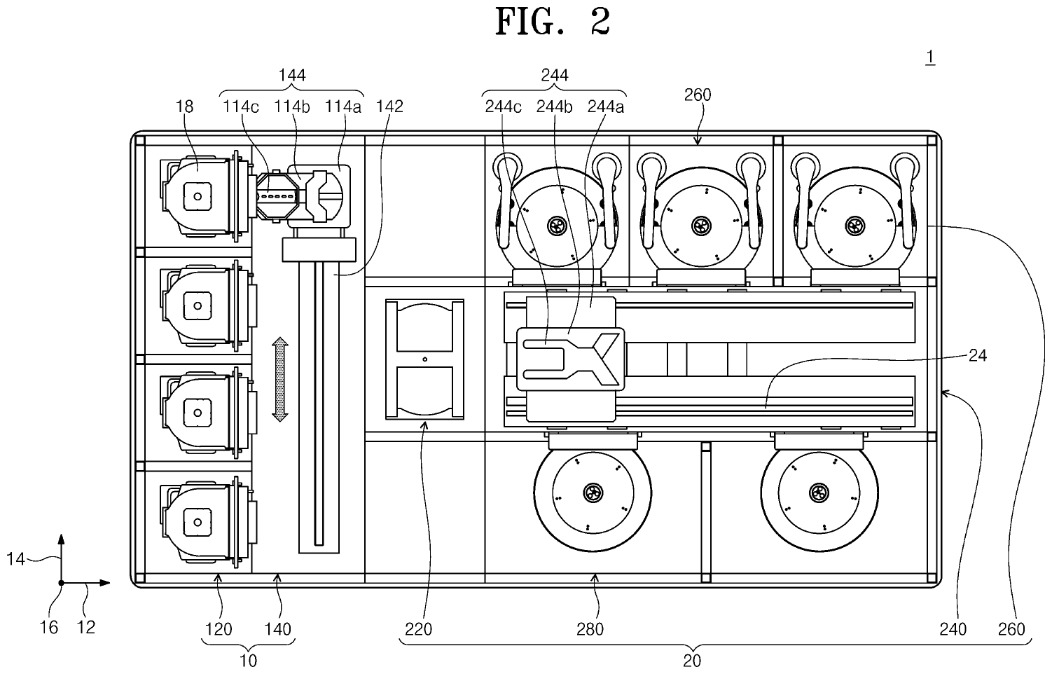

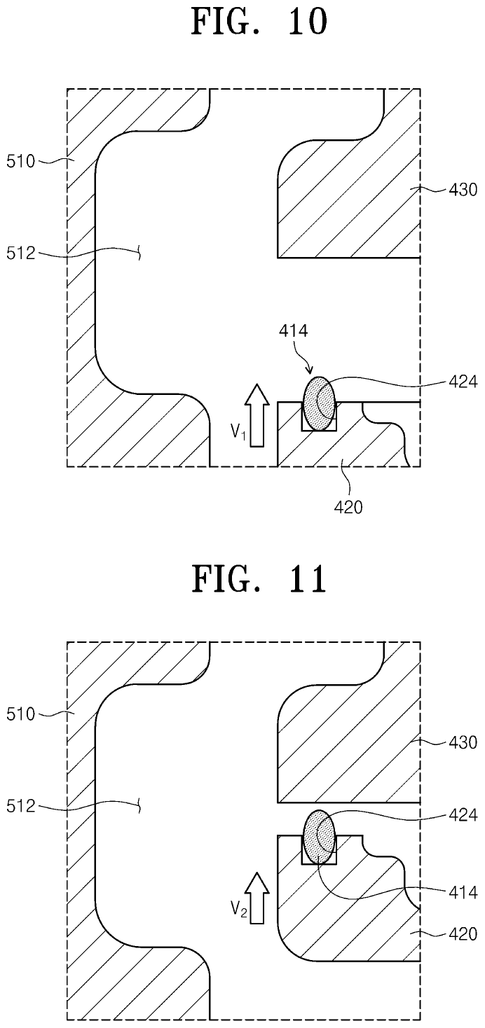

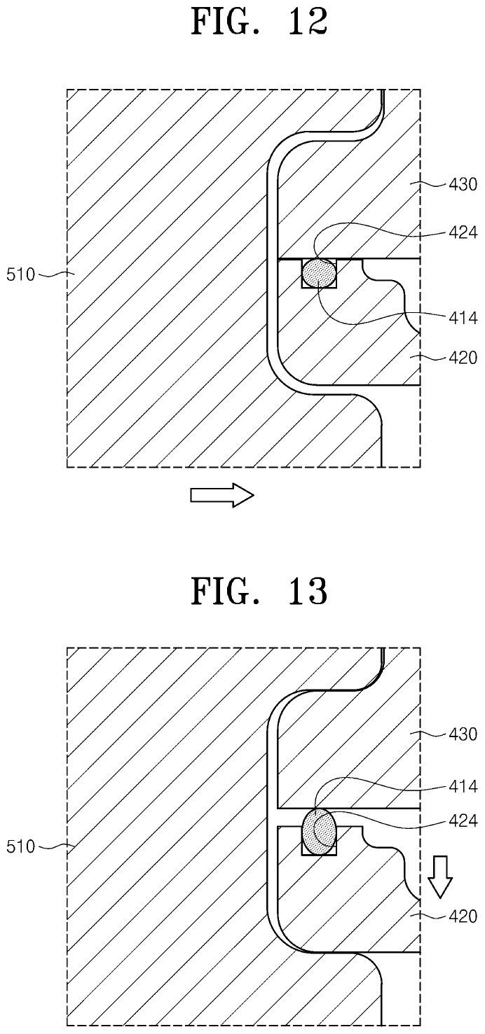

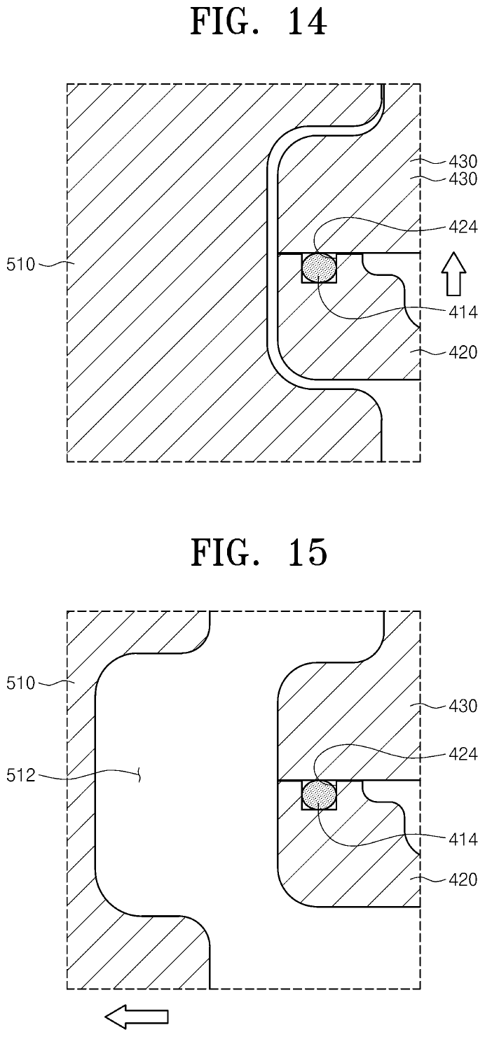

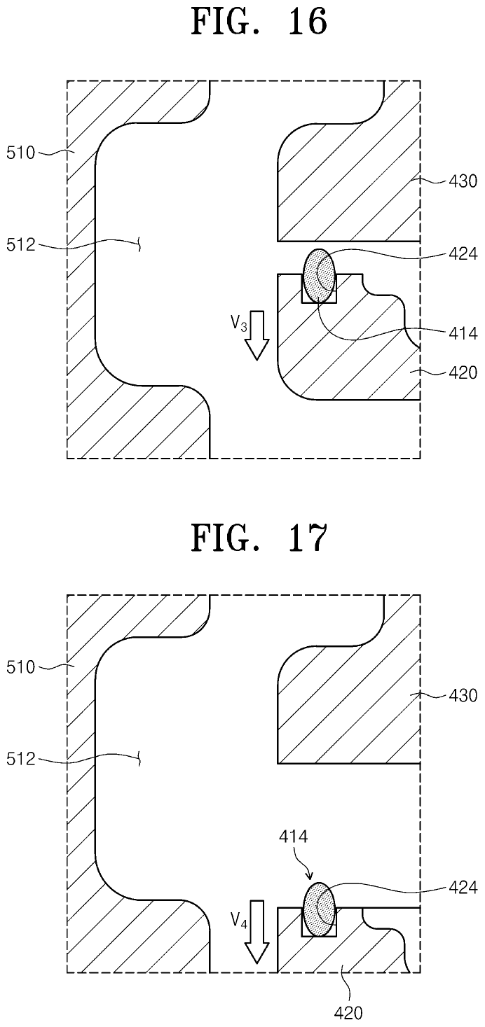

Hereinafter, embodiments of the inventive concept will be described in detail with reference to FIGS. 2 to 17.

FIG. 2 is a plan view illustrating substrate processing equipment 1 according to an embodiment of the inventive concept.

Referring to FIG. 2, the substrate processing equipment 1 has an index module 10 and a processing module 20. The index module 10 has load ports 120 and a transfer frame 140. The load ports 120, the transfer frame 140, and the processing module 20 are sequentially arranged in a row. Hereinafter, the direction in which the load ports 120, the transfer frame 140, and the processing module 20 are arranged is referred to as a first direction 12, a direction perpendicular to the first direction 12 when viewed from above is referred to as a second direction 14, and a direction perpendicular to the plane including the first direction 12 and the second direction 14 is referred to as a third direction 16.

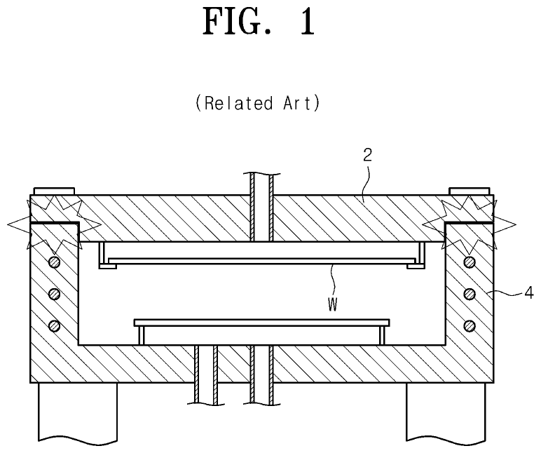

Carriers 18 having substrates W received therein are placed on the load ports 120. The plurality of load ports 120 are arranged in a row along the second direction 14. FIG. 1 illustrates one example that the index module 10 includes four load ports 120. However, the number of load ports 120 may be increased or decreased depending on conditions such as process efficiency and footprint of the processing module 20. Each of the carriers 18 has a plurality of slots (not illustrated) that are formed therein to support the edges of the substrates W. The plurality of slots are arranged along the third direction 16, and the substrates W are stacked one above another with a spacing gap therebetween in the carrier 18 along the third direction 16. A front opening unified pod (FOUP) may be used as the carrier 18.

The processing module 20 has a buffer unit 220, a transfer chamber 240, first process units 260, and second process units 280. The transfer chamber 240 is arranged such that the longitudinal direction thereof is parallel to the first direction 12. The first process units 260 are arranged on one side of the transfer chamber 240 along the second direction 14, and the second process units 280 are arranged on an opposite side of the transfer chamber 240 along the second direction 14. The first process units 260 and the second process units 280 may be symmetric to each other with respect to the transfer chamber 240. Some of the first process units 260 may be arranged along the longitudinal direction of the transfer chamber 240. Furthermore, other first process units 260 are stacked one above another. That is, the first process units 260 may be arranged in an A×B array (A and B being natural numbers of 1 or larger) on the one side of the transfer chamber 240. Here, A denotes the number of first process units 260 arranged in a row along the first direction 12, and B denotes the number of first process units 260 arranged in a column along the third direction 16. In the case where four or six first process units 260 are disposed on the one side of the transfer chamber 240, the first process units 260 may be arranged in a 2×2 or 3×2 array. The number of first process units 260 may be increased or decreased. The second process units 280 may also be arranged in an M×N array (M and N being natural numbers of 1 or larger) similarly to the first process units 260. Here, M and N may be equal to A and B, respectively. Alternatively, both the first process units 260 and the second process units 280 may be provided on only the one side of the transfer chamber 240. In another case, the first process units 260 and the second process units 280 may be provided in a single layer on the one side and the opposite side of the transfer chamber 240, respectively. In addition, unlike those described above, the first process units 260 and the second process units 280 may be provided in various arrangements.

The buffer unit 220 is disposed between the transfer frame 140 and the transfer chamber 240. The buffer unit 220 provides a space in which the substrates W stay before transferred between the transfer chamber 240 and the transfer frame 140. The buffer unit 220 has a plurality of slots (not illustrated) therein, on which the substrates W are placed. The slots (not illustrated) are spaced apart from each other along the third direction 16. The buffer unit 220 is open at one side facing the transfer frame 140 and at an opposite side facing the transfer chamber 240.

The transfer frame 140 transfers the substrates W between the carriers 18 placed on the load ports 120 and the buffer unit 220. An index rail 142 and an index robot 144 are provided in the transfer frame 140. The index rail 142 is arranged such that the longitudinal direction thereof is parallel to the second direction 14. The index robot 144 is mounted on the index rail 142 and linearly moves along the index rail 142 in the second direction 14. The index robot 144 has a base 144a, a body 144b, and a plurality of index arms 144c. The base 144a is installed so as to be movable along the index rail 142. The body 144b is coupled to the base 144a. The body 144b is movable on the base 144a along the third direction 16. Furthermore, the body 144b is rotatable on the base 144a. The plurality of index arms 144c are coupled to the body 144b and are movable forward and backward relative to the body 144b. The plurality of index arms 144c may operate individually. The index arms 144c are stacked one above another with a spacing gap therebetween along the third direction 16. Some of the index arms 144c may be used to transfer substrates W from the processing module 20 to the carriers 18, and the other index arms 144c may be used to transfer substrates W from the carriers 18 to the processing module 20. Accordingly, particles generated from substrates W to be processed may be prevented from adhering to processed substrates W in the process in which the index robot 144 transfers the substrates W between the carriers 18 and the processing module 20.

The transfer chamber 240 transfers substrates W between the buffer unit 220, the first process units 260, and the second process units 280. A guide rail 242 and a main robot 244 are provided in the transfer chamber 240. The guide rail 242 is arranged such that the longitudinal direction thereof is parallel to the first direction 12. The main robot 244 is mounted on the guide rail 242 and linearly moves on the guide rail 242 along the first direction 12.

The first process unit 260 and the second process unit 280 may sequentially perform processes on one substrate W. For example, the first process unit 260 may perform a chemical process, a rinsing process, and a first drying process on the substrate W, and the second process unit 280 may perform a second drying process on the substrate W. In this case, an organic solvent may be used in the first drying process, and a supercritical fluid may be used in the second drying process. An isopropyl alcohol (PIA) solution may be used as the organic solvent, and carbon dioxide (CO₂) may be used as the supercritical fluid. Alternatively, the first process unit 260 may not perform the first drying process.

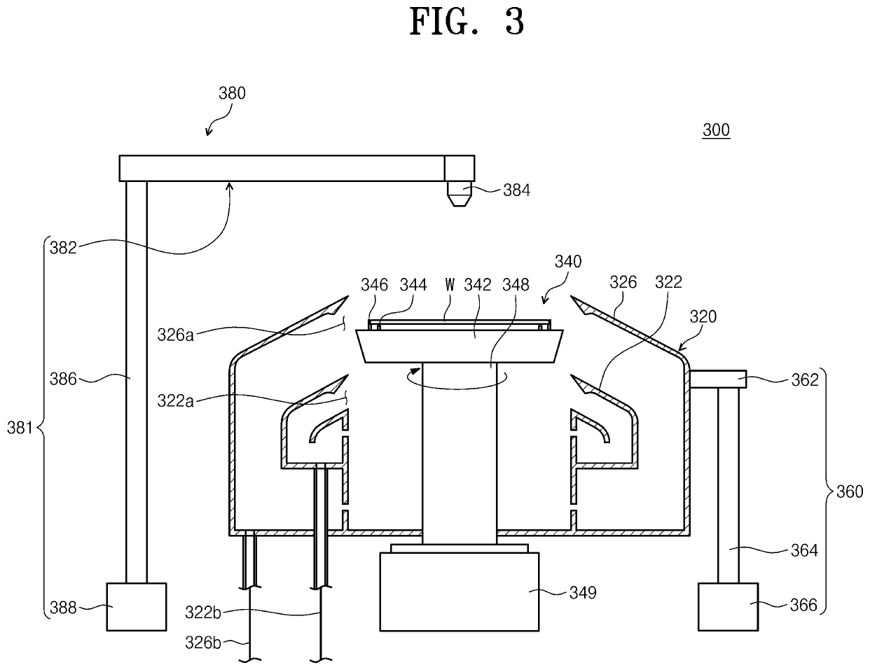

Hereinafter, a substrate processing apparatus 300 provided in the first process unit 260 will be described. FIG. 3 is a sectional view illustrating the apparatus 300 for cleaning the substrate W in the first process unit 260 of FIG. 2. Referring to FIG. 3, the substrate processing apparatus 300 has a processing vessel 320, a spin head 340, a lifting unit 360, and a dispensing member 380. The processing vessel 320 has a space in which the substrate W is processed. The processing vessel 320 is open at the top thereof. The processing vessel 320 has an inner recovery bowl 322 and an outer recovery bowl 326. The recovery bowls 322 and 326 recover different processing fluids used in processes. The inner recovery bowl 322 has an annular ring shape surrounding the spin head 340, and the outer recovery bowl 326 has an annular ring shape surrounding the inner recovery bowl 322. An inner space 322a of the inner recovery bowl 322 and a space 326a between the outer recovery bowl 326 and the inner recovery bowl 322 function as inlets through which the processing fluids are introduced into the inner recovery bowl 322 and the outer recovery bowl 326, respectively. The recovery bowls 322 and 326 have recovery lines 322b and 326b connected thereto, which vertically extend downward from bottom surfaces of the recovery bowls 322 and 326. The recovery lines 322b and 326b drain the processing liquids out of the recovery bowls 322 and 326. The drained processing liquids may be reused through an external processing liquid regeneration system (not illustrated).

The spin head 340 is disposed inside the processing vessel 320. The spin head 340 supports and rotates the substrate W during processing. The spin head 340 has a body 342, support pins 334, chuck pins 346, and a support shaft 348. The body 342 has an upper surface with a substantially circular shape when viewed from above. The support shaft 348 that is rotatable by a motor 349 is fixedly coupled to a bottom surface of the body 342. The plurality of support pins 334 are arranged on an edge portion of the upper surface of the body 342 with a predetermined spacing gap therebetween and protrude upward from the body 342. The support pins 334 are arranged to have an annular ring shape as a whole by a combination thereof. The support pins 334 support the edge of the back side of the substrate W such that the substrate W is spaced apart from the upper surface of the body 342 by a predetermined distance. The plurality of chuck pins 346 are disposed farther away from the center of the body 342 than the support pins 334. The chuck pins 346 protrude upward from the body 342. The chuck pins 346 support the side of the substrate W to prevent the substrate W from deviating from the correct position to a side when the spin head 340 rotates. The chuck pins 346 linearly move between a standby position and a support position along the radial direction of the body 342. The standby position is farther away from the center of the body 342 than the support position. The chuck pins 346 are located in the standby position when the substrate W is loaded onto or unloaded from the spin head 340. The chuck pins 346 are located in the support position when a process is performed on the substrate W. In the support position, the chuck pins 346 are brought into contact with the side of the substrate W.

The lifting unit 360 linearly moves the processing vessel 320 in the vertical direction. The height of the processing vessel 320 relative to the spin head 340 varies as the processing vessel 320 is vertically moved. The lifting unit 360 has a bracket 362, a movable shaft 364, and an actuator 366. The bracket 362 is fixedly attached to an outer wall of the processing vessel 320. The movable shaft 364 is fixedly coupled to the bracket 362 and vertically moved by the actuator 366. When the substrate W is placed on the spin head 340 or lifted up from the spin head 340, the processing vessel 320 moves downward to cause the spin head 340 to protrude above the processing vessel 320. Furthermore, when a process is performed, the height of the processing vessel 320 is adjusted depending on the type of a processing liquid supplied to the substrate W such that the processing liquid is introduced into a preset recovery bowl.

Unlike that described above, the lifting unit 360 may vertically move the spin head 340 instead of the processing vessel 320.

The dispensing member 380 dispenses a processing liquid onto the substrate W. The dispensing member 380 has a nozzle support rod 382, a nozzle 384, a support shaft 386, and an actuator 388. The support shaft 386 is arranged such that the longitudinal direction thereof is parallel to the third direction 16, and the actuator 388 is coupled to a lower end of the support shaft 386. The actuator 388 rotates and lifts the support shaft 386. The nozzle support rod 382 is coupled perpendicular to an upper end of the support shaft 386 that is opposite to the lower end of the support shaft 386 to which the actuator 388 is coupled. The nozzle 384 is mounted on a bottom surface of a distal end of the nozzle support rod 382. The nozzle 382 is moved between a process position and a standby position by the actuator 388. The process position is defined as a position where the nozzle 384 is located directly above the processing vessel 320, and the standby position is defined as a position where the nozzle 384 deviates from directly above the processing vessel 320. One or more dispensing members 380 may be provided. In the case where the plurality of dispensing members 380 are provided, a chemical, a rinsing solution, and an organic solvent may be dispensed through the different dispensing members 380. The chemical may be a liquid that has the property of strong acid or strong base. The rinsing liquid may be deionized water. The organic solvent may be a mixture of isopropyl alcohol vapor and inert gas, or may be an isopropyl alcohol solution.

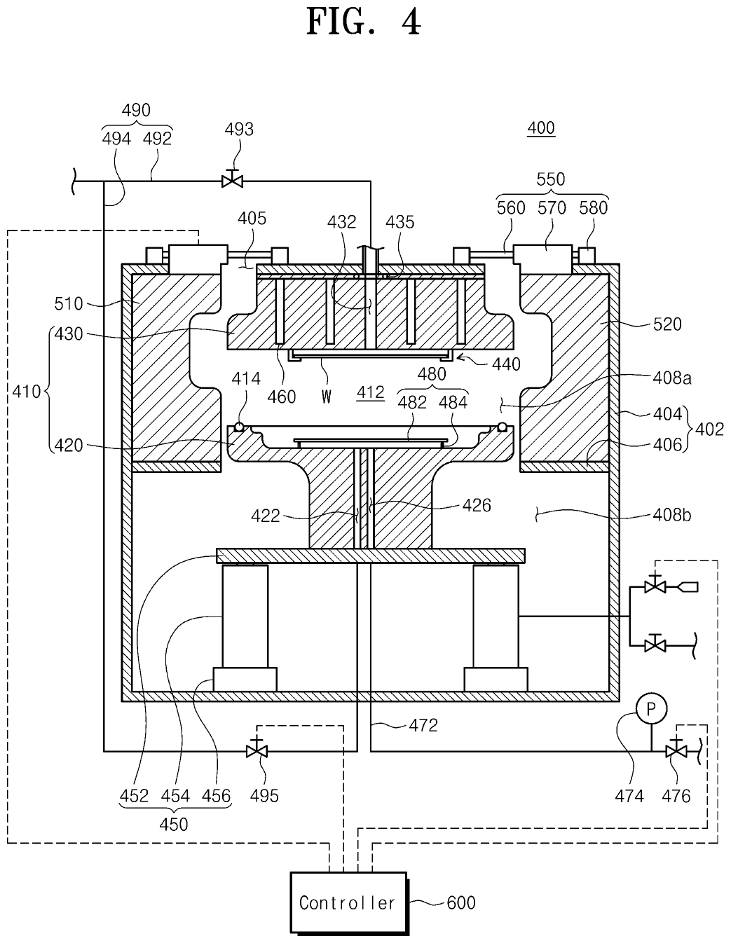

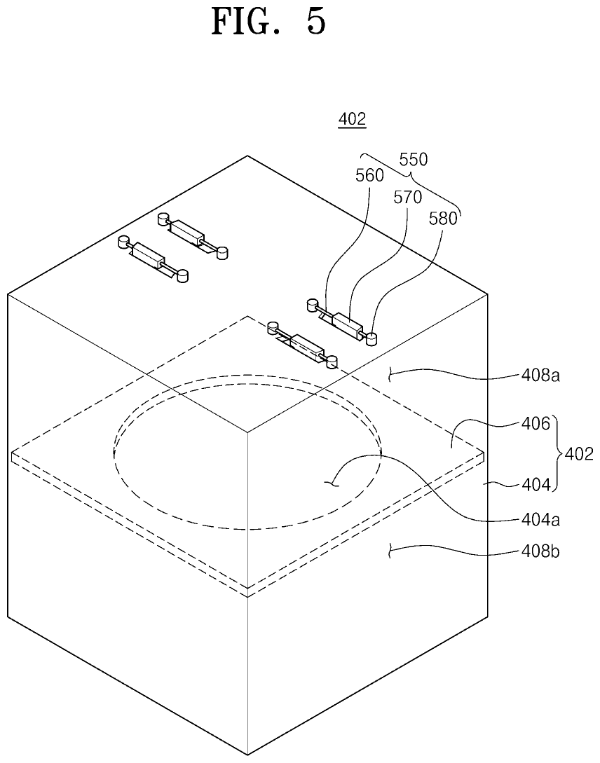

A substrate processing apparatus 400 for performing the second drying process on the substrate W is provided in the second process unit 280. The substrate processing apparatus 400 secondly dries the substrate W that is firstly dried in the first process unit 260. The substrate processing apparatus 400 performs a drying process on the substrate W on which the organic solvent remains. The substrate processing apparatus 400 may perform the drying process on the substrate W by using a supercritical fluid. FIG. 4 is a sectional view illustrating the apparatus 400 for drying the substrate W in the second process unit 280 of FIG. 2, and FIG. 5 is a perspective view illustrating a housing 402 of FIG. 4. Referring to FIGS. 4 and 5, the substrate processing apparatus 400 includes the housing 402, a process chamber 410, a substrate support unit 440, a lifting member 450, a heating member 460, a blocking member 480, an exhaust unit 470, a fluid supply unit 490, a clamping member 500, movable members 550, and a controller 600.

The housing 402 includes a body 404 and an intermediate plate 406. The body 404 may have the shape of a container with a space inside. For example, the body 404 may have a rectangular parallelepiped shape. The body 404 has slit-shaped through-holes 405 formed in an upper surface thereof. The through-holes 405 have the same longitudinal direction at different positions. According to an embodiment, the body 404 may have four through-holes 405, in which two of the through-holes 405 may be located on one side and the other two through-holes 405 may be located on an opposite side. Alternatively, the body 404 may have an even number of through-holes 405, for example, two, six, or more through-holes 405. The through-holes 405 function as passages through which the movable members 550 and the clamping member 500 are connected.

The intermediate plate 406 is located in the body 404. The intermediate plate 406 divides the inside of the body 404 into an upper space 408a and a lower space 408b. The intermediate plate 406 has a plate shape with an empty space 404a. A second body 420 may be inserted into the empty space 404a. The empty space 404a may have a larger diameter than a lower end of the second body 420. The process chamber 410 and the clamping member 500 may be located in the upper space 408a, and the lifting member 450 may be located in the lower space 408b. The movable members 550 may be located on an outer wall of the housing 402.

The process chamber 410 has a processing space 412 therein, in which the substrate W is processed. The process chamber 410 seals the processing space 412 from the outside while the substrate W is processed. The process chamber 410 includes the second body 420, a first body 430, and a sealing member 414. A bottom surface of the second body 420 has a step. The second body 420 has a shape in which a central portion of the bottom surface thereof is located in a lower position than an edge portion of the bottom surface. The second body 420 is vertically movable between the upper space 408a and the lower space 408b of the body 404 by the lifting member 450. A lower supply port 422 and an exhaust port 426 are formed in the bottom surface of the second body 420. The lower supply port 422 may be eccentrically located off the central axis of the second body 420 when viewed from above. The lower supply port 422 functions as a passage through which a supercritical fluid is supplied into the processing space 412.

The first body 430 is combined with the second body 420 to form the processing space 412 inside. The first body 430 is provided as an upper body 430 located over the second body 420, and the second body 420 is provided as a lower body 420 located under the first body 430. The first body 430 is located in the upper space 408a of the housing 402. The first body 430 is coupled to a ceiling surface of the body 404 by a buffer member 435. The buffer member 435 may be formed of an elastic material. The buffer member 435 may be a plate spring or a coil spring. For example, the buffer member 435 may be a spring. An upper surface of the first body 430 has a step. The first body 430 has a shape in which a central portion of the upper surface thereof is located in a higher position than an edge portion of the upper surface. The first body 430 has an upper supply port 432 formed therein. The upper supply port 432 functions as a passage through which a supercritical fluid is supplied into the processing space 412. The upper supply port 432 may be located to coincide with the center of the first body 430. According to an embodiment, the first body 430 and the second body 420 may be formed of metal.

The sealing member 414 seals the gap between the first body 430 and the second body 420. The sealing member 414 is located between the first body 430 and the second body 420. The sealing member 414 has an annular ring shape. For example, the sealing member 414 may be implemented with an O-ring. The sealing member 414 may be provided on a lower end surface of the first body 430 or on an upper end surface of the second body 420. In this embodiment, the sealing member 414 is provided on the upper end surface of the second body 420. The second body 420 has a sealing groove formed on the upper end surface thereof, into which the sealing member 414 is inserted. A portion of the sealing member 414 is inserted into the sealing groove, and the remaining portion protrudes above the sealing groove. The sealing member 414 may be formed of an elastic material.

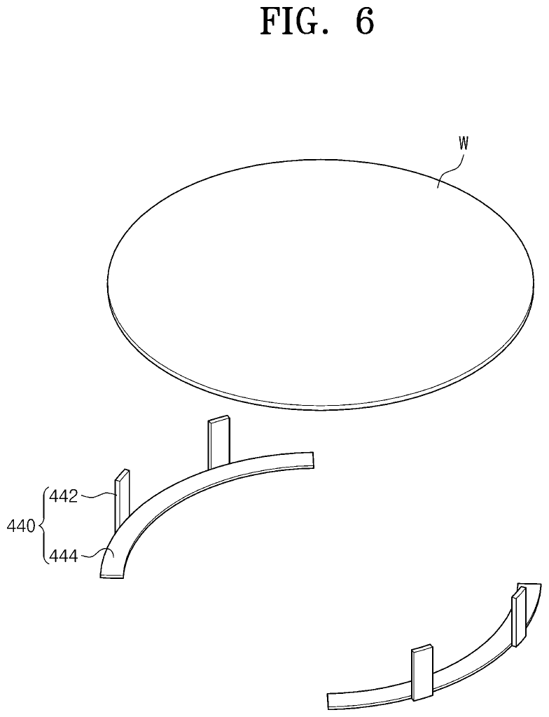

The substrate support unit 440 supports the substrate W in the processing space 412. FIG. 6 is a perspective view illustrating the substrate support unit 440 of FIG. 4. Referring to FIG. 6, the substrate support unit 440 supports the substrate W such that a surface of the substrate W that is to be processed faces upward. The substrate support unit 440 includes support rods 442 and substrate holding parts 444. The support rods 442 have a bar shape extending downward from the bottom surface of the first body 430. The number of support rods 442 may be four. The substrate holding parts 444 support an edge region of the bottom side of the substrate W. The plurality of substrate holding parts 444 support different regions of the substrate W. For example, the number of substrate holding parts 444 may be two. The substrate holding parts 444 have a rounded plate shape when viewed from above. The substrate holding parts 444 are located inward of the support rods 442 when viewed from above. The substrate holding parts 444 are combined together to form a ring shape. The substrate holding parts 444 are spaced apart from each other.

Referring again to FIGS. 4 and 5, the lifting member 450 adjusts the relative position between the first body 430 and the second body 420. The lifting member 450 raises or lowers one of the first body 430 and the second body 420 to cause the one body to be spaced apart from, or brought into close contact with, the other body. The lifting member 450 raises or lowers one of the first body 430 and the second body 420 to cause the process chamber 410 to be moved to an open position or a closed position. Here, the open position is a position where the first body 430 and the second body 420 are spaced apart from each other, and the closed position is a position where the first body 430 and the second body 420 are brought into close contact with each other. That is, in the open position, the processing space 412 is open to the outside, and in the closed position, the processing space 412 is sealed from the outside. In this embodiment, the lifting member 450 is located in the lower space 408b to raise or lower the second body 420, and the position of the first body 430 is fixed. Alternatively, the second body 420 may be fixed, and the first body 430 may be raised or lowered relative to the second body 420. In this case, the lifting member 450 may be located in the upper space 408a.

The lifting member 450 includes a support plate 452, lifting shafts 454, and actuators 456. The support plate 452 supports the second body 420 in the lower space 408b. The second body 420 is fixedly coupled to the support plate 452. The support plate 452 has a circular plate shape. The support plate 452 has a larger diameter than the empty space 404a. Accordingly, even in the closed position, the lower end of the second body 420 is located in the lower space 408b. The lifting shafts 454 support a bottom surface of the support plate 452 in the lower space 408b. The lifting shafts 454 are fixedly coupled to the support plate 452. The plurality of lifting shafts 454 are arranged along the circumferential direction. The actuators 456 raise or lower the lifting shafts 454. The actuators 456 are coupled to the lifting shafts 454 in a one-to-one manner. When driving forces are provided to the actuators 456, the second body 420 and the lifting shafts 454 are raised, and the first body 430 and the second body 420 are moved to the closed position in which the processing space 412 is closed. The driving forces are identically provided to, or released from, the actuators 456. Accordingly, the plurality of lifting shafts 454 may be located at the same height while being raised or lowered, and the support plate 452 and the second body 420 may be raised or lowered in a horizontal state. For example, the actuators 456 may be cylinders or motors.

The heating member 460 heats the processing space 412. The heating member 460 heats the supercritical fluid supplied into the processing space 412 to the critical temperature or more to maintain the supercritical fluid in the supercritical fluid phase. The heating member 460 includes a plurality of heaters 460. The heaters 460 have a bar or rod shape, and the longitudinal directions of the heaters 460 are parallel to each other. The longitudinal directions of the heaters 460 are perpendicular to the directions in which clamps 510 and 520 are moved. For example, the longitudinal directions of the heaters 460 are parallel to the directions in which the bodies 420 and 430 are moved. The heaters 460 cannot be inserted through side surfaces of the bodies 420 and 430 because side portions of the bodies 420 and 430 are clamped. The heaters 460 may be buried in the wall of at least one of the first body 430 and the second body 420. For example, the heaters 460 may generate heat by receiving electric power from the outside. In this embodiment, the heaters 460 are provided in the first body 420. However, the heaters 460 may be provided in the first body 430 and the second body 420. Alternatively, the heaters 460 may be provided in the second body 420 rather than the first body 430.

The blocking member 480 prevents the supercritical fluid supplied from the lower supply port 422 from being directly supplied to the non-processed surface of the substrate W. The blocking member 480 includes a blocking plate 482 and support rods 484. The blocking plate 482 is located between the lower supply port 422 and the substrate support unit 440. The blocking plate 482 has a circular plate shape. The blocking plate 482 has a diameter smaller than the inner diameter of the second body 420. The blocking plate 482 has a diameter sufficient to hide both the lower supply port 422 and the exhaust port 426, when viewed from above. For example, the blocking plate 482 may have a diameter corresponding to, or larger than, the diameter of the substrate W. The support rods 484 support the blocking plate 482. The plurality of support rods 484 are arranged along the circumferential direction of the blocking plate 482. The support rods 484 are spaced apart from each other by a predetermined interval.

The exhaust unit 470 releases the atmosphere in the processing space 412. Process by-products generated in the processing space 412 are released through the exhaust unit 470. The release of the by-products may be naturally or forcedly performed. Furthermore, the exhaust unit 470 may adjust the pressure in the processing space 412 while releasing the process by-products. The exhaust unit 470 includes an exhaust line 472 and a pressure measurement member 474. The exhaust line 472 is connected to the exhaust port 426. An exhaust valve 476 installed on the exhaust line 472 may adjust the displacement volume of the processing space 412. The pressure measurement member 474 is installed in the exhaust line 472 and measures the pressure in the exhaust line 472. The pressure measurement member 474 is located upstream of the exhaust valve 476 with respect to the exhaust direction. The pressure in the processing space 412 may be reduced to the atmospheric pressure or a pressure corresponding to the outside of the process chamber 410 by the exhaust unit 470.

The fluid supply unit 490 supplies a processing fluid into the processing space 412. The processing fluid is supplied in a supercritical state at its critical temperature and critical pressure. The fluid supply unit 490 includes an upper supply line 492 and a lower supply line 494. The upper supply line 492 is connected to the upper supply port 432. The processing fluid flows sequentially through the upper supply line 492 and the upper supply port 432 and is then supplied into the processing space 412. An upper valve 493 is installed on the upper supply line 492. The upper valve 493 opens or closes the upper supply line 492. The lower supply line 494 connects the upper supply line 492 and the lower supply port 422. The lower supply line 494 branches from the upper supply line 492 and is connected to the lower supply port 422. That is, the processing fluids supplied from the upper supply line 492 and the lower supply line 494 may be of the same type. The processing fluid flows sequentially through the lower supply line 494 and the lower supply port 422 and is then supplied into the processing space 412. A lower valve 495 is installed on the lower supply line 494. The lower valve 495 opens or closes the lower supply line 494.

According to an embodiment, the processing fluid may be supplied from the lower supply port 422 that faces the non-processed surface of the substrate W, and thereafter the processing fluid may be supplied from the upper supply port 432 that faces the surface of the substrate W that is to be processed. Accordingly, the processing fluid may be supplied into the processing space 412 through the lower supply line 494 and may then be supplied into the processing space 412 through the upper supply line 492. The reason is to prevent the initially supplied processing fluid from being supplied to the substrate W below the critical pressure or the critical temperature.

The clamping member 500 clamps the first body 430 and the second body 420 that are located in the closed position. Accordingly, the first body 430 and the second body 420 may be prevented from being spaced apart from each other even though the pressure in the processing space 412 rises during processing.

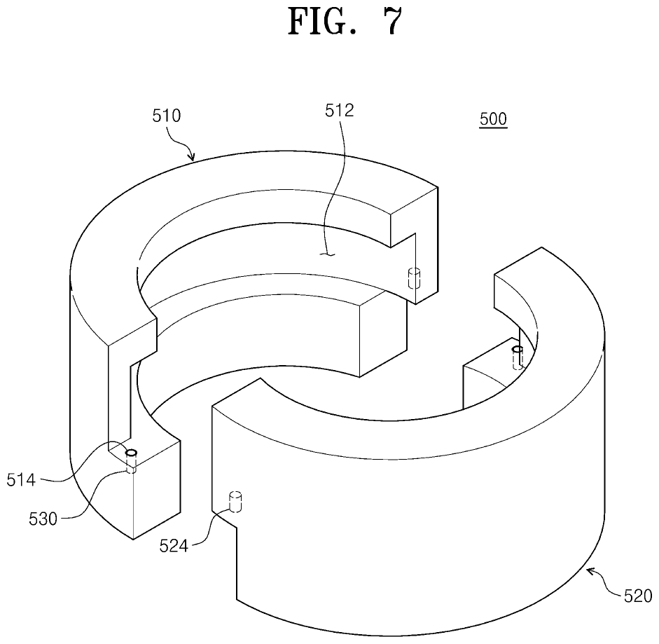

FIG. 7 is a perspective view illustrating the clamping member 500 of FIG. 4. Referring to FIG. 7, the clamping member 500 includes the first clamp 510, the second clamp 520, and locking pins 530. The first clamp 510 and the second clamp 520 are located on both sides of the process chamber 410. According to an embodiment, the first clamp 510 and the second clamp 520 are located to face each other with the process chamber 410 therebetween. The first clamp 510 and the second clamp 520 have a shape surrounding the process chamber 410. Each of the first clamp 510 and the second clamp 520 has a clamp groove 512 formed on an inner surface that faces the process chamber 410. Edge portions of the first and second bodies 430 and 420 in the closed position may be inserted into the clamp grooves 512. That is, the edge portion of the first body 430 and the edge portion of the second body 420 are provided as clamped regions. The vertical length P₂ of the clamp grooves 512 is longer than the length P₁ from an upper end of the edge portion of the first body 430 in the closed position to a lower end of the edge portion of the second body 420 in the closed position. That is, the vertical length P₂ of the clamp grooves 512 is longer than the vertical length P₁ of the clamping regions of the first and second bodies 430 and 420 located in the closed position.

The clamping member 500 is movable to a clamping position or an unclamping position. Here, the clamping position is defined as a position where the first clamp 510 and the second clamp 520 move toward each other to clamp the first body 430 and the second body 420, and the unclamping position is defined as a position where the first clamp 510 and the second clamp 520 are separated from the first body 430 and the second body 420. In the clamping position, the first clamp 510 and the second clamp 520 are combined together to form an annular ring shape. For example, one of the first clamp 510 and the second clamp 520 may have a vertical cross section with the shape of “C” or “⊂”, and the other may have a vertical cross section that is symmetric to the vertical cross section of the one clamp with respect to the vertical axis.

One side surface of the first clamp 510 that is brought into contact with the second clamp 520 has a step. An opposite side surface of the second clamp 520 that is brought into contact with the first clamp 510 has a step. The one side surface of the first clamp 510 and the opposite side surface of the second clamp 520 have shapes complementary to each other. According to an embodiment, the one side surface of the first clamp 510 may have a step with an upper end longer than its lower end, and the opposite side surface of the second clamp 520 may have a step with an upper end shorter than its lower end. A first pin recess 514 in which the locking pin 530 is located is formed in the stepped region of the first clamp 510, and a second pin recess 524 is formed in the stepped region of the second clamp 520. The first pin recess 514 and the second pin recess 524 are directed in a direction perpendicular to the moving direction of the clamping member 500. In the clamping position, the first pin recess 514 and the second pin recess 524 are located to face each other. According to an embodiment, in the clamping position, the locking pin 530 may protrude from the first pin recess 514 and may be inserted into the second pin recess 524. Furthermore, the first pin recess 514 may be additionally formed in the second clamp 520, and the second pin recess 524 may be additionally formed in the first clamp 510.

Referring again to FIGS. 4 and 5, the movable members 550 move the clamping member 500 between the clamping position and the unclamping position. The movable members 550 move the clamping member 500 in the perpendicular direction to the moving direction of the process chamber 410. Each of the movable members 550 includes a guide rail 560, a bracket 570, and an actuating member 580. The guide rail 560 is located outside the housing 402. The guide rail 560 is located adjacent to the upper space 408a in which the first body 430 is located. The guide rail 560 is mounted on an upper surface of the housing 402. The guide rail 560 has a longitudinal direction perpendicular to the moving direction of the process chamber 410. The guide rails 560 of the movable members 550 have the same longitudinal direction. According to an embodiment, the guide rails 560 and the through-holes 405 are provided in equal numbers. The guide rails 560 have a longitudinal direction parallel to the through-holes 405. The guide rails 560 are located to overlap the through-holes 405 when viewed from above. The bracket 570 fixedly couples the guide rail 560 and the clamping member 500. As many brackets 570 as the guide rails 560 are provided. According to an embodiment, when viewed from above, the first clamp 510 may be connected to the guide rails 560 located on one side, and the second clamp 520 may be connected to the guide rails 560 located on the other side. The actuating member 580 actuates the guide rail 560 to cause the clamping member 500 to move to the clamping position or the unclamping position along the longitudinal direction of the guide rail 560.

The controller 600 controls the lifting member 450 and the movable members 550. The controller 600 controls the lifting member 450 to move the process chamber 410 to the closed position or the open position and controls the movable members 550 to move the clamping member 500 to the clamping position or the unclamping position. Furthermore, the controller 600 may control the fluid supply unit 490 to make the pressure in the processing space 412 higher than the pressure applied to the second body 420 in the closed position. According to an embodiment, the controller 600 may move the clamping member 500 from the unclamping position to the clamping position when the process chamber 410 is moved from the open position to the closed position. The controller 600 may adjust the ascent speed of the second body 420 to a first speed of V1 and a second speed of V2 and may adjust the descent speed of the second body 420 to a third speed of V3 and a fourth speed of V4.

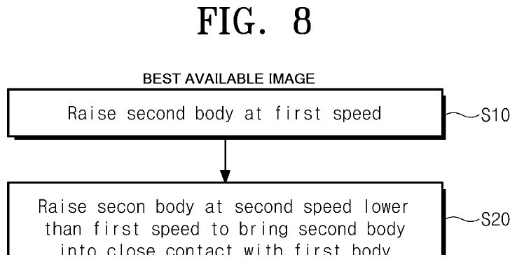

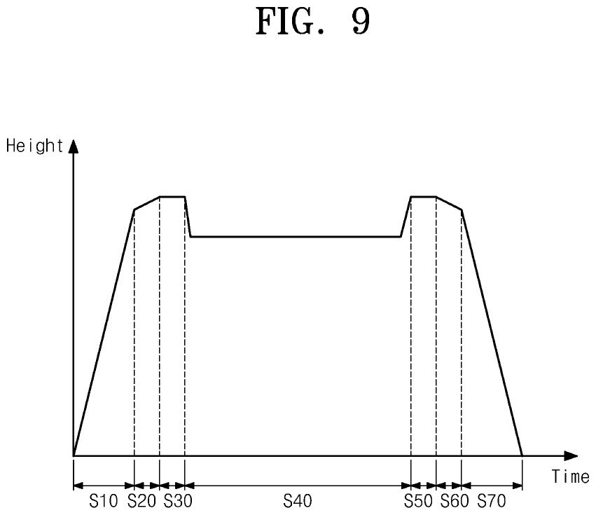

Next, a method for processing a substrate using the above-described substrate processing apparatus 400 will be described. FIG. 8 is a flowchart illustrating a process of processing a substrate using the apparatus of FIG. 4. FIG. 9 is a graph depicting the position of the second body 420 in each step of the flowchart illustrated in FIG. 8. FIGS. 10 to 17 are views illustrating the process of processing the substrate using the apparatus of FIG. 4. Referring to FIGS. 8 to 17, in the process of processing the substrate W, the process chamber 410 is moved such that high-speed closing step S10, low-speed closing step S20, clamping step S30, processing step S40, unclamping step S50, low-speed opening step S60, and high-speed opening step S70 are performed in a serial order. Hereinafter, it will be exemplified that high-speed closing step S10 is performed with the process chamber 410 located in the open position and the clamping member 500 located in the unclamping position.

In high-speed closing step S10, the clamping member 500 is located in the unclamping position, and the second body 420 is raised toward the first body 430 at the first speed of V1. In high-speed closing step S10, the first body 430 and the second body 420 are spaced apart from each other. When the second body 420 is moved to a position adjacent to the first body 430, low-speed closing step S20 is performed.

In low-speed closing step S20, the second body 420 is moved toward the first body 430 at the second speed of V2. The second body 420 is raised at the second speed of V2 and moved to the closed position in which the second body 420 is brought into close contact with the first body 430. Here, the second speed V2 is lower than the first speed V1. In this case, the impact applied to each body may be alleviated, as compared with when the second body 420 collides with the first body 430 at the first speed of V1. When the first body 430 and the second body 420 are brought into close contact with each other, the processing space 412 is sealed from the outside. At this time, the actuators 456 apply a first pressure to the second body 420. For example, the actuators 456 may apply the first pressure to the second body 420 from low-speed closing step S20 to unclamping step S50.

In clamping step S30, the clamping member 500 is moved from the unclamping position to the clamping position. The clamping member 500 is moved to the clamping position to clamp the process chamber 410. In the process of moving the clamping member 500, a collision of the clamping member 500 with the process chamber 410 may be prevented because the first body 430 and the second body 420 are brought into close contact with each other and the vertical length P₂ of the clamp grooves 512 is longer than the length P₁ from the upper end of the edge portion of the first body 430 to the lower end of the edge portion of the second body 420. When the process chamber 410 is clamped, processing step S40 is performed.

In processing step S40, a supercritical fluid is supplied into the processing space 412. As the supercritical fluid is supplied into the processing space 412, the pressure in the processing space 412 is gradually raised. The processing space 412 is pressurized to a second pressure by the processing fluid. Here, the second pressure is higher than the first pressure. The second pressure is higher than the critical pressure of the processing fluid. A drying process is performed on the substrate W at the second pressure. Accordingly, the first body 430 and the second body 420 are moved away from each other and brought into close contact with the clamping member 500. At this time, the processing space 412 is sealed from the outside by the sealing member 414. When the drying process is completely performed on the substrate W, the supply of the processing fluid is stopped, and the atmosphere in the processing space 412 is released by the exhaust unit 470. The atmosphere in the processing space 412 is released until the pressure in the processing space 412 reaches a third pressure lower than the first pressure. For example, the third pressure may be the atmospheric pressure or a pressure close to the atmospheric pressure. When the pressure in the processing space 412 is reduced to the third pressure, the first body 430 and the second body 420 are brought into close contact with each other again by the first pressure applied to the second body 420 by the actuators 456. Unclamping step S50 is performed.

When unclamping step S50 is performed, the clamping member 500 is moved from the clamping position to the unclamping position. In the process of moving the clamping member 500, a collision of the clamping member 500 with the process chamber 410 may be prevented because the first body 430 and the second body 420 are brought into close contact with each other. When the clamping member 500 is moved to the unclamping position, low-speed opening step S60 is performed.

In low-speed opening step S60, the second body 420 is moved away from the first body 430 at the third speed of V3. The second body 420 is lowered at the third speed of V3. Accordingly, rapid expansion of the processing space 412 and a negative pressure in the processing space 412 may be prevented. When the second body 420 is spaced apart from the first body 430, high-speed opening step S70 is performed.

In high-speed opening step S70, the second body 420 is lowered at the fourth speed of V4 and moved to the open position. Here, the fourth speed V4 is higher than the third speed V3. Accordingly, it is possible to rapidly open the process chamber 410 while preventing expansion of the processing space 412. For example, the first speed V1 may be equal to the fourth speed V4, and the second speed V2 may be equal to the third speed V3.

According to the embodiments of the inventive concept, the first body or the second body is moved at a high speed and then moved at a low speed in the process of closing the processing space. Accordingly, impact between the first body and the second body may be alleviated.

Furthermore, according to the embodiments of the inventive concept, the first body or the second body is moved at a low speed and then moved at a high speed in the process of opening the processing space. Accordingly, a negative pressure may be prevented from being temporarily generated in the processing space.

In addition, according to the embodiments of the inventive concept, the clamping member clamps or unclamps the first body and the second body in close contact with each other. Accordingly, a collision of the clamping member with the bodies may be minimized.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for processing a substrate, the apparatus comprising:
a chamber having a first body and a second body that are combined with each other to form a processing space inside;
an actuator configured to close or open the processing space by moving a relative position between the first body and the second body;
a substrate support unit configured to support the substrate in the processing space;
a gas supply unit configured to supply a gas into the processing space to process the substrate;
a controller configured to control the actuator and the gas supply unit; and
a clamping member configured to clamp the chamber when the first body and the second body are in close contact to seal the processing space;
wherein in a processing step of processing the substrate in the processing space, the controller controls the actuator to apply a first pressure to move the first body and the second body toward each other and controls the gas supply unit to apply a second pressure by the gas supplied into the processing space, and
wherein the second pressure is higher than the first pressure.

2. The apparatus of claim 1, wherein the controller controls the actuator to sequentially perform a high-speed closing step of moving the first body or the second body at a first speed and a low-speed closing step of moving the first body or the second body at a second speed lower than the first speed, at a time of closing the chamber

3. The apparatus of claim 2, wherein the controller controls the actuator to sequentially perform a low-speed opening step of moving the first body or the second body at a third speed and a high-speed opening step of moving the first body or the second body at a fourth speed higher than the third speed, at a time of opening the chamber.

4. The apparatus of claim 1, further comprising a movable member configured to move the clamping member to a clamping position in which the clamping member clamps the first body and the second body or an unclamping position in which the clamping member is separated from the first body and the second body,
wherein the controller controls the gas supply unit and the movable member to perform a clamping step of moving the clamping member to the clamping position, the processing step by supplying the gas into the processing space, with the first body and the second body in close contact to seal the processing space, and an unclamping step of moving the clamping member to the unclamping position, between the low-speed closing step and the low-speed opening step.

5. The apparatus of claim 4, further comprising an exhaust unit configured to release an atmosphere in the processing space,
wherein the controller controls the exhaust unit to make pressure in the processing space lower than the first pressure after the processing space is pressurized to the second pressure in the processing step.

6. The apparatus of claim 1, wherein the second pressure is higher than a critical pressure of the gas.
